(19) United States
(12) Patent Application Publication
(10) Pub. No.: US 2005/0141209 A1
(43) Pub. Date: Jun. 30, 2005

(54) Electronic apparatus and shielding device thereof

(76) Inventor: Yi-Jen Chen, Lujhou City (TW)

Correspondence Address: BIRCH STEWART KOLASCH & BIRCH, PO BOX 747, FALLS CHURCH, VA, 22040-0747, US

(21) Appl. No.: 10/947,205

(22) Filed: Sep. 23, 2004

(30) Foreign Application Priority Data
Dec. 30, 2003 (TW) 092137507

(51) Int. Cl. H01R 24/00; H05K 7/14; H05K 7/18

(52) U.S. Cl. 361/800

(57) ABSTRACT

A shielding device includes a shell and a touch portion. In this case, the shell shields an electronic device. The touch portion is disposed on the shell and touches the electronic device. An electronic apparatus, including a circuit board, a shell and a touch portion, is also provided. In this case, at least one electronic device is disposed on the circuit board. The shell shields the electronic device. The touch portion is on the shell and touches the electronic device.

### BACKGROUND OF THE INVENTION

1. Field of Invention

The invention relates to a shielding device and, in particular, to a shielding device, which has a touch portion for heat dissipation and is for shielding an electronic.

2. Related Art

Most of electronic apparatuses work accompanying with electromagnetic radiation, and different electronic apparatuses are always interfered to each other due to the electromagnetic radiation. This is so-called electromagnetic interference (EMI), which may affect other electronic apparatus. More particularly, electronic apparatuses of high sensitive may malfunction, and human body may be injured.

Electromagnetic waves appear as two forms, including irradiation and conduction. When the frequency of an electromagnetic wave is less than 10 MHz, the electromagnetic wave appears as the form of conduction. When the frequency of an electromagnetic wave is greater than 10 MHz, the electromagnetic wave always appears as the form of irradiation. To prevent the radiation and interference of electromagnetic waves, the containers and conducting wires of electronic products should include high-electromagnetic-conducted materials for shielding electromagnetic waves. In such a case, the thickness of a shielding device should be thicker for shielding electromagnetic waves of lower frequency, and that of the shielding device should be thinner for shielding electromagnetic waves of higher frequency.

To reduce the EMI, a conventional electronic apparatus 1, as shown in FIG. 1, provides a shielding cap 12, which is made of an electric-conducted material, on an electronic device 11. The shielding cap 12 has connection pins 121 for engaging with a circuit board 13, so that the electronic device 11 can be contained between the shielding cap12 and the circuit board 13. The shielding cap 12 is capable of erasing the accumulation of static electricity, and absorbing electromagnetic field. Thus, the electromagnetic wave can be shielded, and the EMI is prevented.

Since the present electronic products become more compact and lighter, and the heat generated by electronic devices is increased, the heat density is rapidly increased. The heat of the electronic devices may not be dissipated easily. Therefore, if the heat-dissipating mechanism for the electronic devices is ineffective, the performance and reliability of the electronic product is deathly affected. Moreover, the lifetime of the electronic product is shortened.

If a heat sink is directly mounted on the electronic device, and then a shielding cap of larger size is designed for capping the entire circuit board, the required shielding cap may have increased volume, which increases the production cost.

Furthermore, the shielding cap of the electronic apparatus has an opening for providing a heat-dissipating component on the electronic device, so as to achieve the objectives of heat dissipation and EMI prevention. However, since the heat-dissipating component is attached to the electronic device with an adhesive, the heat dissipation is poor. Moreover, since the heat-dissipating component is attached and is not replaced easily, the repairing of the electronic device is difficult when the electronic device has defects. In such a case, the whole circuit board may be discarded as junk.

It is therefore a subjective of the invention to provide a shielding device and an electronic apparatus for solving the above-mentioned problem.

### SUMMARY OF THE INVENTION

In view of the above, the invention is to provide a shielding device and an electronic apparatus, which can achieve heat dissipation and EMI prevention.

To achieve the above, the shielding device of the invention includes a shell and a touch portion. In the invention, the shell is annularly provided at the periphery of an electronic device and has a touch portion to touch the electronic device.

In addition, an electronic device of the invention includes a circuit board, a shell, and a touch portion. In the invention, at least one electronic device is mounted the circuit board. The shell is annularly provided at the periphery of the electronic device to shield the electronic device. The shell has a touch portion to touch the electronic device.

Moreover, an electronic device of the invention includes a circuit board, a shell, a touch portion, and a chassis. In the invention, at least one electronic device is mounted the circuit board. The shell is annularly provided at the periphery of the electronic device to shield the electronic device. The shell further includes a first sidewall, while the chassis includes a second sidewall. The first sidewall is annularly provided at the periphery of the second sidewall and is engaged to the second sidewall.

As mentioned above, the shielding device and electronic apparatus of the invention utilizes the shielding device to accommodate the circuit board therein. Thus, the shielding device of the invention can provide the function of EMI prevention as well as the prior art. Since the shielding device of the invention further includes a touch portion for directly touching the electronic device, the entire shielding device can also function as a thermal conductive material, which enhances the heat dissipation of the electronic device. Therefore, it is unnecessary to install an additional heat-dissipating component, resulting in the decreased size of the shielding device. The manufacturing cost can thus be saved and the manufacturing processes can be simplified.

### BRIEF DESCRIPTION OF THE DRAWINGS

The invention will become more fully understood from the detailed description given hereinbelow illustration only, and thus is not limitative of the present invention, and wherein:

FIG. 1 is a schematic view showing the conventional electronic apparatus;

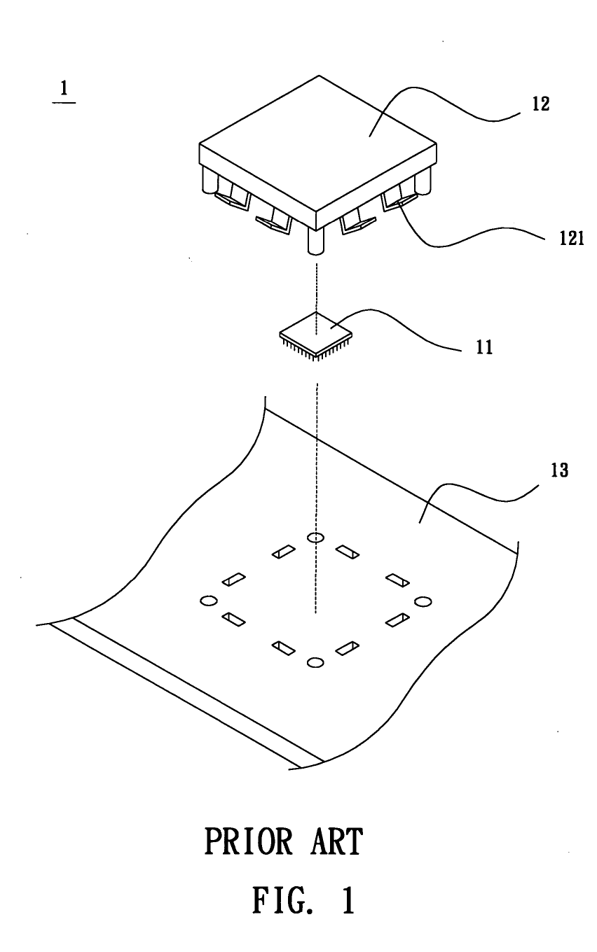

FIG. 2 is a schematic view showing a shielding device of the invention;

FIG. 3 is an explosion diagram showing an electronic apparatus of the invention; and

FIG. 4 is an explosion diagram showing another electronic apparatus of the invention.

### DETAILED DESCRIPTION OF THE INVENTION

The shielding device and electronic apparatus according to the embodiments of the invention will be described herein below with reference to relevant drawings, wherein the same elements are assigned with the same reference numbers.

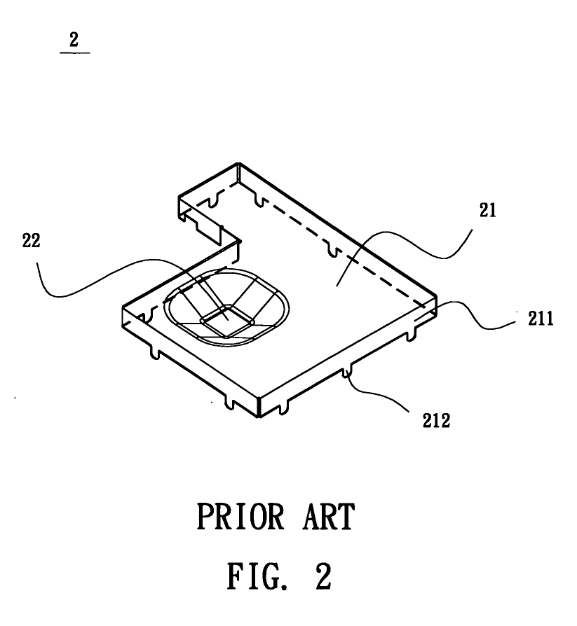

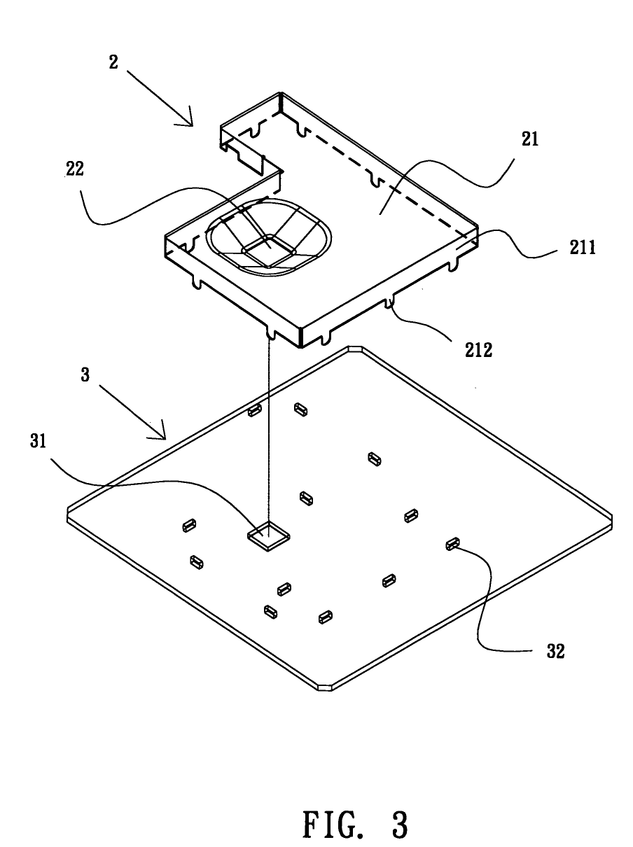

At first, FIG. 2 and FIG. 3 are referred to illustrate the shielding device according to the preferred embodiment of the invention.

With reference to FIGS. 2 and 3, a shielding device 2 according to a preferred embodiment of the invention includes a shell 21 and a touch portion 22. The shell 21 is used to shield an electronic device 31 such as a chip or a thermal ceramic device. The shell 21 further includes a first sidewall 211, which is annularly provided at the periphery of the electronic device 31. The shell 21 is mounted on a circuit board 3, which is a print circuit board.

One side of the first sidewall 211 is connected to the shell 21, and the first sidewall 211 is annularly provided at the periphery of the shell 21. At least one assembling portion 212 is formed on the other side of the first sidewall 211. In this embodiment, the assembling portion 212 is a convex means for connecting the shielding device 2 to the circuit board 3.

Referring to FIG. 3, the assembling portion 212 can be inserted into the plug hole 32 of the circuit board 3. In such a case, the dual in-line package (DIP) technology is utilized to assemble the shielding device 2 with the circuit board 3. In addition, surface mount technology (SMT) is also a proper choice to connect the shielding device 2 to the circuit board 3. In this method, a welding pad is previously formed on the circuit board 3, and a layer of tin is then printed on the circuit board 3. The shielding device 2 is positioned on the layer of tin. After a reflowing process at a high temperature, the convex means can be welded and mounted on the circuit board 3.

The touch portion 22 is disposed on the shell 21 and touches the electronic device 31. The shell 21 can be punched to form the touch portion 22. In practice, the touch portion 22 can be a convex portion or a concave portion of the shell 21. For example, as shown in FIG. 3, the touch portion 22, which is a concave portion of the shell 21, is positioned above the electronic device 31 to touch the electronic device 31. The depth of the concave touch portion 22 or the height of the convex touch portion 22 is determined depending on the height of the electronic device 31 to be shielded. In such cases, the shell 21 is punched to form the proper touch portion 22 for connecting the electronic device 31. Accordingly, the touch portion 22 of the shielding device 2 mounted on the circuit board 3 directly connects the electronic device 31 for dissipating heat.

It should be noted that the shape of shell 21 of the shielding device 2, for matching actual requirements, could be rectangle or polygon. The shell 21 and the first sidewall 211 are integrally formed.

Hereinafter, an electronic apparatus according to a preferred embodiment of the invention is described with reference to FIG. 3.

As shown in FIG. 3, an electronic apparatus of the invention includes a circuit board 3, a shell 21, and a touch portion 22. In this embodiment, the circuit board 3 at least has an electronic device 31 mounted thereon and a plurality of plug holes 32. The electronic apparatus could be a motherboard or a computer. The circuit board 3 is a printed circuit board, and at least one electronic device 31, such as a chip or a thermal ceramic component, is mounted thereon.

The shell 21 is to shield the electronic device 31. The shell 21 further includes a first sidewall 211, which is annularly disposed at the periphery of the electronic device 31. One side of the first sidewall 211 has at least one assembling portion 212 for combining with the circuit board 3.

The assembling portion 212 is a convex means for connecting the shield module 2 to the circuit board 3. As shown in FIG. 3, the assembling portion 212 may be inserted into the plug hole 32 of the circuit board 3. In such a case, the dual in-line package (DIP) technology is utilized to assemble the shielding device 2 with the circuit board 3. In addition, surface mount technology (SMT) is also a proper choice to connect the shielding device 2 to the circuit board 3. In this case, a welding pad is previously formed on the circuit board 3, and a layer of tin is then printed on the circuit board 3. The shielding device 2 is positioned on the layer of tin. After a reflowing process at a high temperature, the convex means can be welded and mounted on the circuit board 3.

Please refer to FIG. 3 again. In the present embodiment, the shell 21 can be punched to form the touch portion 22. In practice, the touch portion 22 can be a convex portion or a concave portion of the shell 21. For example, the touch portion 22 of FIG. 3 is a concave portion of the shell 21. The depth of the concave touch portion 22 or the height of the convex touch portion 22 is determined depending on the height of the electronic device 31 to be shielded. In such cases, the punch process of the shell 21 is well controlled to form the proper touch portion 22 for connecting the electronic device 31. Regarding to the shielding device 2 mounted on the circuit board 3, the touch portion 22 of the shielding device 2 directly connects the electronic device 31 for dissipating heat.

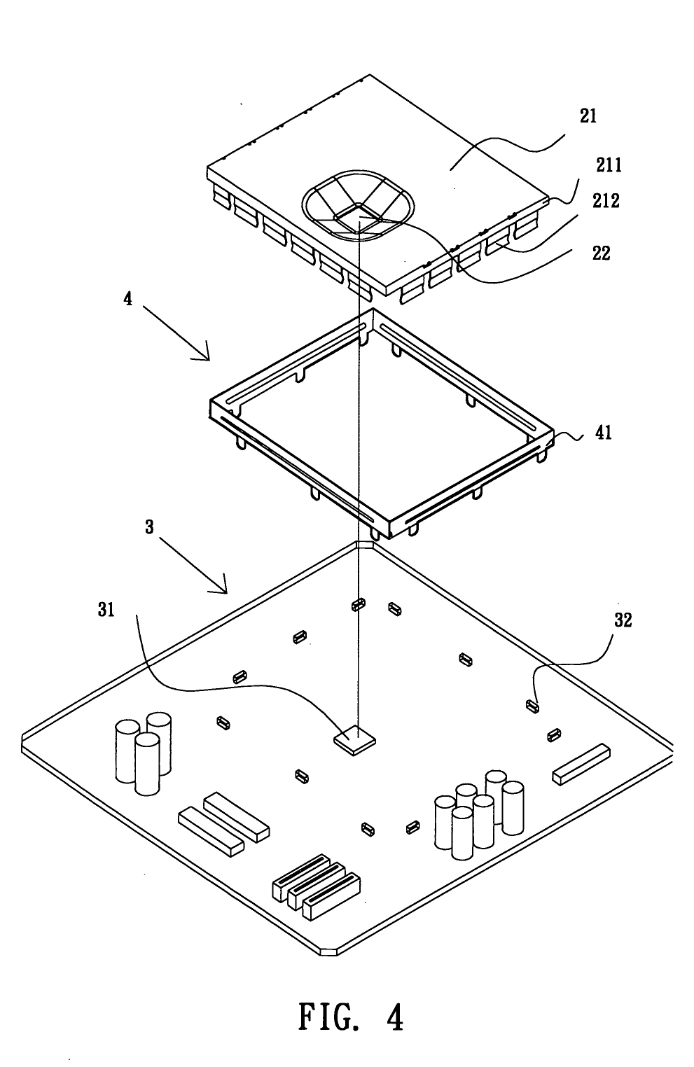

Hereinafter, an additional electronic apparatus according to another preferred embodiment of the invention is described with reference to FIG. 4.

With reference to FIG. 4, an electronic apparatus according another preferred embodiment of the invention includes a shell 21, a touch portion 22, a circuit board 3 and a chassis 4. The shell 21 is used to shield an electronic device 31. The shell 21 further includes a first sidewall 211, which is annularly provided at the periphery of the electronic device 31. One side of the first sidewall 211 includes at least one assembling portion 212. In this embodiment, The assembling portion 212 includes a plurality of wavy engagements distributed along the first sidewall 211.

In the current embodiment, the chassis 4 is a frame mounted on the circuit board 3 and has the function of EMI prevention. The shell 21 uses the assembling portion 212 to engage with the second sidewall 41 of the chassis 4. The first sidewall 211 is annularly disposed around the second sidewall 41 and engages with the second sidewall 41. In other words, excepting the SMT and the DIP technology, the assembling portion 212 can be a wavy engagement to engage with the chassis 4.

To sum up, the shielding device and electronic apparatus of the invention utilizes the shielding device to accommodate the circuit board therein. Thus, the shielding device of the invention can provide the function of EMI prevention as well as the prior art. Moreover, the shielding device of the invention further includes a touch portion for directly touching the electronic device, and the entire shielding device can also function as a thermal conductive material, which enhances the heat dissipation of the electronic device. Therefore, it is unnecessary to install an additional heat-dissipating component, resulting in the decreased size of the shielding device. The manufacturing cost can thus be saved and the manufacturing processes can be simplified. Since the shielding device is installed on the circuit board by way of DIP technology, SMT, or engaging method to contact with the electronic device, the repairing procedure of the electronic apparatus is easy and fast. Wherein, the repairing procedure only includes the step of removing the shielding device. This is quite different from the prior art, which adheres the heat-dissipation component on the electronic device and is hard to perform repairing procedure. The prior art may results in totally damage of the entire circuit board. In addition, since the shielding device is integrated formed, the EMI would not leakage easily, which can enhance the effect of EMI prevention.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

1. A shielding device, comprising:
a shell, which is to shield an electronic device; and
a touch portion, which is disposed on the shell and touches the electronic device.

2. The shielding device of claim 1, wherein the shell further comprises a first sidewall, the first sidewall is annularly provided at the periphery of the electronic device, and the shell is mounted on a circuit board.

3. The shielding device of claim 1, wherein the touch portion is a convex portion of the shell.

4. The shielding device of claim 1, wherein the touch portion is a concave portion of the shell.

5. The shielding device of claim 2, wherein the shell and the first sidewall are integrally formed.

6. The shielding device of claim 2, wherein at least one assembling portion is formed on one side of the first sidewall.

7. The shielding device of claim 6, wherein the assembling portion is a convex means for connecting to the circuit board.

8. The shielding device of claim 6, wherein the assembling portion is welded to circuit board.

9. The shielding device of claim 6, wherein the shielding device further comprises a chassis.

10. The shielding device of claim 9, wherein the assembling portion comprises a plurality of wavy engagements distributed along the first sidewall, the chassis further comprises a second sidewall, and the first sidewall is annularly provided at the periphery of the second sidewall and is engaged to the second sidewall.

11. An electronic apparatus, comprising:
a circuit board, on which at least one electronic device is mounted;
a shell, which is to shield the electronic device; and
a touch portion, which is disposed on the shell and touches the electronic device.

12. The electronic apparatus of claim 11, wherein the shell further comprises a first sidewall, and the first sidewall is annularly provided at the periphery of the electronic device.

13. The electronic apparatus of claim 11, wherein the touch portion is a concave portion of the shell.

14. The electronic apparatus of claim 11, wherein the touch portion is a convex portion of the shell.

15. The electronic apparatus of claim 12, wherein the shell and the first sidewall are integrally formed.

16. The electronic apparatus of claim 12, wherein at least one assembling portion is formed on one side of the first sidewall.

17. The electronic apparatus of claim 16, wherein the assembling portion is a convex means for connecting the shielding device to the circuit board.

18. The electronic apparatus of claim 16, wherein the assembling portion is welded to circuit board.

19. The electronic apparatus of claim 12, further comprising:
a chassis, which comprises a second sidewall, wherein the first sidewall is annularly provided at the periphery of the second sidewall and is engaged to the second sidewall.

20. The electronic apparatus of claim 16, wherein the assembling portion comprises a plurality of wavy engagements distributed along the first sidewall.
